(19) United States
(12) Patent Application Publication
(10) Pub. No.: US 2006/0105581 A1
(43) Pub. Date: May 18, 2006

(54) Glycol doping agents in carbon doped oxide films

(76) Inventors: Jeffery D. Bielefeld, Forest Grove, OR (US); George A. Antonelli, Portland, OR (US); Kevin L. Peterson, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/993,325

(22) Filed: Nov. 18, 2004

(51) Int. Cl. H01L 21/469

(52) U.S. Cl. 438/786; 438/789; 438/790; 257/632

(57) ABSTRACT

A method for forming a carbon doped oxide (CDO) film comprises doping an organosilane precursor material with a glycol material and using the doped organosilane precursor material in a deposition process to form the CDO film. The glycol material may be propylene glycol (PD). The PD-doped CDO films formed using the methods of the invention have been shown to have an increase in strength (e.g., an increase in Young's modulus) with a minimal effect on the dielectric constant of the PD-doped CDO film.

### BACKGROUND

For years, silicon dioxide (SiO₂) has been an established insulating material for the semiconductor industry. Silicon dioxide had been the material of choice for use as an interlayer dielectric material (ILD) to insulate electrical devices and interconnects. Recently, however, silicon dioxide is beginning to reach its limitations in addressing leading-edge device demands. This is particularly highlighted by the semiconductor industry's move towards smaller device dimensions.

Conventional replacements for silicon dioxide as an ILD material are low-k dielectric materials. These are materials with dielectric constants generally around 3.0 and below. The primary driver for the transition to low-k materials is reducing noise and interference that arises between different interconnect lines, commonly referred to as cross-talk. As interconnects become narrower and more closely packed together, the capacitance between interconnects increases and gives rise to the adverse signal distortion effects of cross-talk. Common low-k dielectric materials are able to reduce this cross-talk on the order of 40% to 50%.

Carbon doped oxide (CDO) is one of the potential low-k dielectric materials that can achieve a dielectric constant as low as 2.2 and is expected to be suitable for the next generation multilevel interconnection. Standard CDO films are produced by the fragmentation and the resulting deposition of an organo-silane precursor in a plasma deposition process. By varying the standard process conditions such as precursor flow, helium flow, radio-frequency (RF) power, and chamber pressure, the physical properties of the resulting CDO film can be varied. It has been determined, unfortunately, that for a given precursor system, the Young's Modulus of the film is directly proportional to its dielectric constant. CDO precursor systems therefore have a trade-off in their resulting thin film properties between mechanical properties and dielectric constants. In processes requiring higher mechanical strength, CDO films must therefore be replaced by films with higher mechanical strength but also higher dielectric constants.

### BRIEF DESCRIPTION OF THE DRAWINGS

FIG. 1 is a method for forming a standard carbon doped oxide film.

FIG. 2 is a method for forming a novel carbon doped oxide film in accordance with an implementation of the invention.

FIG. 3 is a Fourier-Transform Infrared analysis of a novel carbon doped oxide film and a conventional carbon doped oxide film.

FIG. 4 is a graph of experimental data showing how a carbon doped oxide film formed in accordance with the invention results in improved mechanical properties.

### DETAILED DESCRIPTION

Described herein are systems and methods of producing low-k carbon doped oxide (CDO) dielectric films with high mechanical strength. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

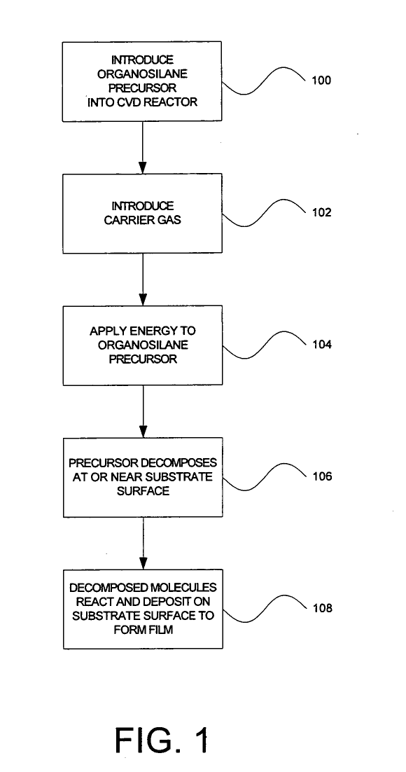

FIG. 1 shows a conventional method for forming a carbon doped oxide (CDO) dielectric film. A chemical vapor deposition (CVD) process is used to deposit the CDO film on a substrate, such as a semiconductor wafer. A CVD process is a versatile technique often used in the semiconductor industry for deposition of material on various substrates. Generally, a gas or vapor precursor material is transformed into solids such as thin films, powders, or various structured materials inside a CVD reactor.

As shown in FIG. 1, an organosilane precursor material may be introduced into the CVD reactor as the precursor material for a CDO dielectric film (process 100). A carrier gas is also introduced into the CVD reactor with the organosilane precursor (process 102). The carrier gas may be helium gas which also serves as a plasma stabilization component. The helium carrier gas may be used to dilute the organosilane precursor as well as to help create a flow into and out of the CVD reactor. The flow into the CVD reactor carries in the organosilane precursor and the exit flow out of the CVD reactor removes volatile by-products of the deposition process.

Energy is applied to the organosilane precursor material in the CVD reactor (process 104). The energy may be in the form of thermal energy using, for instance, resistive heating (e.g., a tube furnace), radiant heating (e.g., a quartz tungsten halogen lamp), or inductive heating (e.g., radio-frequency (RF) radiation). Alternately, the energy may be photo energy such as ultraviolet radiation, visible light radiation, or laser energy. In some instances, a plasma-enhanced chemical vapor deposition process (PECVD) or a plasma-assisted chemical vapor deposition process (PACVD) may be used. In some conventional processes, a strong electric field is often used to cause a plasma ignition and reduce the amount of applied thermal or photo energy required.

The organosilane molecules decompose from the energy application (and from the electric field if a plasma process is used) at or near the surface of the substrate (process 106). A portion of the decomposed molecules then react and deposit onto the substrate to form a standard CDO dielectric film (process 108).

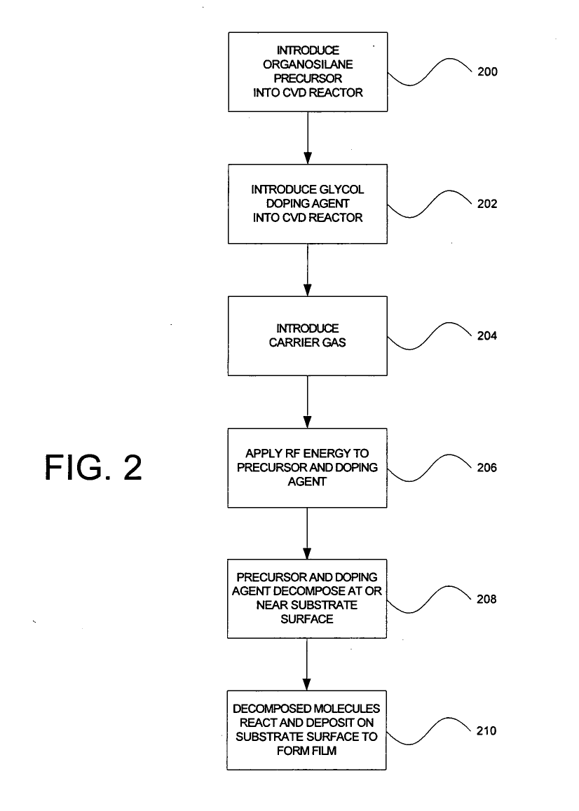

FIG. 2 is an implementation for forming a CDO dielectric film in accordance with the invention. In this implementation, a plasma CVD process, such as a PECVD or a PACVD process, is used to deposit the CDO film on a substrate, such as a semiconductor wafer. The process may be carried out in a CVD reactor with a temperature that may range from 200° C. to 450° C. This temperature may be achieved by heating a chuck that the substrate is mounted on, a wall of the CVD reactor, and/or another internal component of the CVD reactor. The pressure within the CVD reactor may range from 150 pascal (Pa) to 800 Pa.

An organosilane material may be introduced into the CVD reactor as the precursor material for a CDO dielectric film (process 200). Examples of organosilane materials that may be used in the invention include, but are not limited to, trimethylsilane, dimethyldimethoxysilane (DMDMOS), diethoxymethylsilane (DEMS), hexamethyldisiloxane (HMDSO), as well as other organosilane materials. In some implementations, the organosilane material may be introduced into the CVD reactor at a flow rate that ranges from 50 standard cubic centimeters per minute (sccm) to 400 sccm.

In accordance with the invention, a glycol doping agent may be introduced into the CVD reactor (process 202). In some implementations, the glycol doping agent may be propylene glycol (C₃H₈O₂), ethylene glycol (C₂H₆O₂), or butylene glycol (C₄H₁₀O₂). In some implementations, a combination of two or more of propylene glycol, ethylene glycol, or butylene glycol may be used. The propylene glycol may be 1,2-propanediol. The ethylene glycol may be 1,2-ethanediol. The butylene glycol may be 1,3-butanediol, 2,3-butanediol, or 1,4-butanediol. In some implementations, other glycols may be used.

In some implementations, the glycol doping agent may be mixed with the organosilane precursor prior to being introduced into the CVD reactor. In other implementations, the glycol doping agent may be mixed with the organosilane precursor within the CVD reactor. In some implementations, the ratio of glycol doping agent to precursor may range from 0.0 to 0.5. In some implementations, the ratio may range from 0.00001 to 1.00000. The physical properties of the glycol doping agent, including but not limited to its molecular size and vapor pressure, allow the glycol doping agent to be incorporated in most PECVD deposition processes with relative ease.

A carrier gas may be introduced into the CVD reactor with the organosilane precursor and the glycol doping agent (process 204). In various implementations of the invention, gases such as helium, nitrogen, and argon may be used as the carrier gas. In some implementations, a mixture of helium and nitrogen may be used as the carrier gas. The carrier gas may also serve as a plasma stabilization component, thereby diluting the organosilane precursor and helping to create a flow into and out of the CVD reactor. The flow into the CVD reactor carries the organosilane precursor and the glycol doping agent into the CVD reactor and the exit flow out of the CVD reactor removes volatile by-products of the deposition process.

In an implementation of the invention, helium gas may be used as the carrier gas. The helium gas may be adjusted to stabilize the plasma condition for whichever precursor and additive provides attractive properties in the deposited film. If low precursor flows are used, nitrogen gas may be added to the helium gas to reduce the risk of chamber arcing that may result from the high energy nature of helium plasmas. The addition of nitrogen gas adds another path for dissipating the applied RF radiation. The ratio of helium gas to nitrogen gas may range from 0.1 to 1.0. In some implementations, a gas other than nitrogen may be used to dissipate the RF radiation, such as argon gas, and a plasma stabilization agent other than helium may be used.

Energy is applied to the organosilane precursor material and the glycol doping agent in the CVD reactor (process 206). In an implementation, the energy may be in the form of thermal energy using RF radiation. In some implementations, the frequency of the RF radiation may range from 20 megahertz (MHz) to 35 MHz and the RF radiation may be applied at a rate that ranges from 600 Watts (W) up to 3500 W. In one implementation, the frequency of the RF radiation may be around 27 MHz.

In some implementations of the invention, an optional electric field (e.g., a direct current (DC) bias) may be generated within the CVD reactor to induce a plasma ignition for a PECVD or PACVD process. The DC bias may be generated in a small amount, for instance, at a level that is less than ten percent of the power of the applied RF radiation. If a DC bias is used, the frequency of the RF radiation may be reduced to range from 10 MHz to 20 MHz. For instance, the frequency of the RF radiation may be around 13.5 MHz. In another implementation, an optional extra-low frequency RF radiation may be applied within the CVD reactor to serve the same purpose as the DC bias. The extra-low frequency RF radiation may be on the order of hundreds of kilohertz.

The organosilane molecules and the glycol molecules react at or near the surface of the substrate due to the application of RF radiation (process 208). The product of this reaction is a glycol-doped CDO dielectric film that is deposited on the substrate (process 210).

In some implementations, the addition of propylene glycol as the glycol doping agent during the PECVD process for a CDO dielectric film results in a propylene glycol (PD)-doped CDO film having improved mechanical properties without degrading the dielectric constant of the film. It is believed that the methyl (CH₃) end-groups on the propylene glycol molecule may assist in adding to or maintaining the carbon content of the CDO film, thereby stabilizing or lowering the dielectric constant of the CDO film.

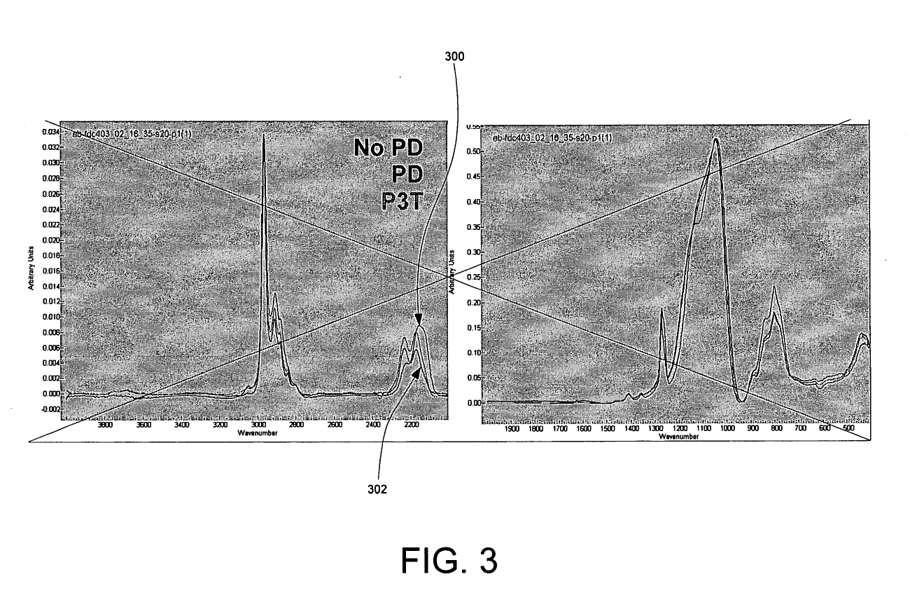

Furthermore, it is believed that the alcohol (OH) end-groups on the propylene glycol molecule may be a potential source of matrix cross-linking during the formation of a silicon dioxide backbone in the CDO film, thereby improving the mechanical properties and the Young's Modulus of the CDO film. For instance, it has been shown that there is an increase in the silicon-oxygen (Si—O) cage structure, which may be at least partially responsible for the increase in the mechanical properties and Young's Modulus of the PD-doped CDO film. FIG. 3 is a Fourier-Transform Infrared (FTIR) analysis of both a PD-doped CDO film 300 and an undoped (standard) CDO film 302 showing how the PD-doped CDO film 300 has a larger concentration of the Si—O molecules (located in the 2200 cm⁻¹ region of the FTIR).

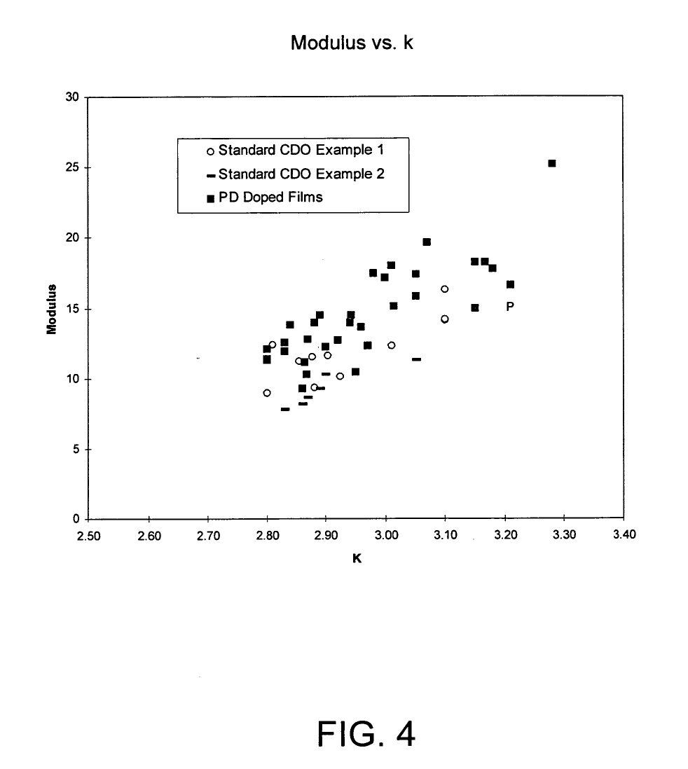

FIG. 4 illustrates experimental data that shows how the addition of the propylene glycol doping agent to the CDO deposition process changes the mechanical properties of the resulting PD-doped CDO film compared to an un-doped film. As shown, the PD-doped CDO film is found to have a higher Young's Modulus compared to the equivalent un-doped CDO film for a given dielectric constant value.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
doping an organosilane precursor material with a glycol material, wherein the resulting doped organosilane precursor material is for use in a deposition process to form a carbon doped oxide film.

2. The method of claim 1, wherein the organosilane precursor material comprises trimethylsilane, dimethyldimethoxysilane, diethoxymethylsilane, or hexamethyldisiloxane.

3. The method of claim 1, wherein the glycol material comprises propylene glycol.

4. The method of claim 1, wherein the glycol material comprises ethylene glycol or butylene glycol.

5. The method of claim 1, wherein a ratio of glycol material to organosilane precursor material is greater than zero and less than or equal to 0.5.

6. The method of claim 1, wherein the deposition process is a chemical vapor deposition process.

7. A method comprising:
providing a chemical vapor deposition (CVD) reactor containing a substrate;
heating an interior of the CVD reactor;
introducing an organosilane precursor material into the CVD reactor;
introducing a glycol doping agent into the CVD reactor;
introducing a carrier gas into the CVD reactor;
applying thermal energy within the CVD reactor; and
depositing a carbon doped oxide film on the substrate.

8. The method of claim 7, wherein the organosilane precursor material comprises trimethylsilane, dimethyldimethoxysilane, diethoxymethylsilane, or hexamethyldisiloxane.

9. The method of claim 7, wherein the glycol doping agent comprises propylene glycol, ethylene glycol, or butylene glycol.

10. The method of claim 7, wherein the heating of the interior comprises heating a chuck within the CVD reactor to a temperature within the range of 200° C. to 450° C.

11. The method of claim 7, wherein the heating of the interior comprises heating a wall within the CVD reactor to a temperature within the range of 200° C. to 450° C.

12. The method of claim 7, wherein the organosilane precursor material is introduced at a flow rate greater than or equal to 50 sccm and less than or equal to 400 sccm.

13. The method of claim 12, wherein a ratio of the glycol doping agent to the organosilane precursor material is greater than zero and less than or equal to 0.5.

14. The method of claim 7, wherein the carrier gas comprises a helium gas.

15. The method of claim 7, wherein the carrier gas comprises a mixture of nitrogen gas and helium gas.

16. The method of claim 7, wherein the applying of thermal energy comprises applying radio-frequency (RF) radiation.

17. The method of claim 16, wherein the RF radiation has a frequency that is greater than or equal to 20 MHz and less than or equal to 35 MHz.

18. The method of claim 17, wherein the RF radiation is applied at a rate that is greater than or equal to 600 W and less than or equal to 3500 W.

19. The method of claim 7, wherein a pressure within the CVD reactor is greater than or equal to 150 Pa and less than or equal to 800 Pa.

20. An apparatus comprising a propylene glycol-doped carbon doped oxide (PD-doped CDO) film formed from an organosilane precursor material and a propylene glycol material.

21. The apparatus of claim 20, wherein the PD-doped CDO film contains a relatively higher amount of silicon-oxygen cage structures compared to a standard carbon doped oxide film.

22. The apparatus of claim 20, wherein the organosilane precursor material comprises trimethylsilane, dimethyldimethoxysilane, diethoxymethylsilane, or hexamethyldisiloxane.

23. The apparatus of claim 20, wherein a ratio of the propylene glycol material to the organosilane precursor material is greater than zero and less than or equal to 0.5.
